(19) United States
(12) Patent Application Publication
(10) Pub. No.: US 2012/0067405 A1
(43) Pub. Date: Mar. 22, 2012

(54) Titania Crystal, Process for Producing the Same, Layered Titania Substrate, and Dye-sensitized Solar Cell

(75) Inventors: Jinting Jiu, Kyoto (JP); Seiji Isoda, Kyoto (JP); Motonari Adachi, Kyoto (JP); Naoki Yoshimoto, Hitachinaka (JP)

(73) Assignee: ROHM CO., LTD., Kyoto-shi, Kyoto (JP)

(21) Appl. No.: 12/672,163

(22) PCT Filed: Aug. 6, 2008
(86) PCT No.: PCT/JP08/64146

§ 371 Date: Jun. 17, 2010

(30) Foreign Application Priority Data
Aug. 7, 2007 (JP) 2007-205110

(51) Int. Cl. H01L 31/0216; B32B 5/22; C01G 23/047; C30B 7/14

(52) U.S. Cl. 136/252; 117/68; 428/317.9; 428/402; 423/610

(57) ABSTRACT

An anatase-type titania crystal having a one-dimensional structure; a process for producing the crystal; and a dye-sensitized solar cell employing the titania crystal. The titania crystal is excellent in photocatalytic characteristics and photoelectric conversion characteristics. The process for titania crystal production is characterized by comprising: a mixing step in which an aqueous solution containing a block copolymer (A) having a hydrophobic block and a hydrophilic block is mixed with an organic solvent (C) containing a titanium alkoxide (B) dissolved therein to thereby give a liquid mixture; a reaction step in which the temperature of the liquid mixture is set at a value in the range of from 120° C. to 180° C. and the pressure of the atmosphere is set so as to result in the saturated vapor pressure at that set temperature to thereby react the liquid mixture and form a titania sol; and a baking step in which the titania sol is heated to produce baked titania particles having a wire shape.

### FIELD OF THE INVENTION

The present invention relates to a technology for improving photocatalytic characteristics and photoelectric conversion characteristics in the field where anatase-type titania crystal is utilized.

### DESCRIPTION OF THE RELATED ART

Utilizing a strong oxidative power of titania in photoexitation, the titania (titanium dioxide) has been widely put into practical use as a photocatalyst for the purpose of antibacterial treating, odor eliminating, antifouling and the like by, for example, coating the titania on a surface of a daily commodity, industrial instrument, building material, leisure goods.

In addition, by applying the strong oxidative power of the titania, a research for practical use of a dye-sensitized solar cell has been conducted. The dye-sensitized solar cell is formed by adsorbing dye on a surface of the titania to generate electricity by converting light energy of irradiation light into electric energy.

It is known that there exist a plurality of polytypes in titania, which have different crystal structures from each other for the same composition and that an anatase-type among the polytypes is excellent in photocatalytic characteristics and photoelectric conversion characteristics in comparison with a rutile-type or a brookite-type.

It is also known that a crystal of the anatase-type titania belongs to a tetragonal system and has a one-dimensional structure extending in a c-axis direction of the unit cell (for example, see non-patent literature 1).
[Non-patent literature 1]: Penn, R. L., and J. F. Banfield, Geochimica Cosmochimica Acta, 63, 1549-1557 (1999)

### DISCLOSURE OF THE INVENTION

### Problems to be Solved by the Invention

It is widely known that photocatalytic characteristics and photoelectric conversion characteristics of titania change depending on a crystal structure of the titania. However, there is no report demonstrating practical advantages of a titania crystal which has a one-dimensional structure.

It is, therefore, an object of the present invention to establish a method for producing a titania crystal which has a one-dimensional structure and a fine diameter, and to clarify advantageous optical properties of the titania crystal.

### Means for Solving the Problems

For solving the forgoing issues, according to the present invention, there is provided a method for producing a titania crystal, which comprises steps of a mixing process for mixing at least an aqueous solution containing a block copolymer (A), which has a hydrophobic block and a hydrophilic block, and being set between pH1 and pH5 and an organic solvent (C) containing titanium alkoxide (B) dissolved therein to prepare a mixed solution, a reaction process for setting a temperature of the mixed solution between 120° C. and 180° C., controlling a pressure of atmosphere at a saturated vapor pressure of the mixed solution at the setting temperature, and reacting the mixed solution to produce titania sol, and a baking process for heating the titania sol and baking a titania crystal which is formed by combining a titania microcrystal one-dimensionally.

Since the invention is configured as described above, a titania crystal, which has a one-dimensional structure formed by combining a plurality of anatase-type titania microcrystals by aligning their crystal axes and a fine diameter having substantially a rectangular cross section whose one side length corresponds to 10 to 50 cycles of an atomic arrangement of titanium, can be obtained.

An experimental result that an aggregate of the titania crystal has better optical characteristics than the aggregate of spherical titania particles was obtained.

### Effects of the Invention

According to the present invention, a method for producing a titania crystal having a one-dimensional structure and a fine diameter is established and a product having excellent photocatalytic characteristics and photoelectric conversion characteristics is provided by utilizing the titania crystal.

### BRIEF DESCRIPTION OF THE DRAWINGS

FIG. 1 is a high-resolution TEM image showing a titania crystal according to the present invention, where the observed titania crystal has a one-dimensional structure which is formed by combining a repeating unit (titania microcrystal) of the structure by aligning a crystal axis thereof;

FIG. 2 is an electron diffraction pattern of an aggregate of the titania crystal shown in FIG. 1, where the pattern shows that a crystal structure of the titania crystal is an anatase-type;

FIG. 3A is a perspective view of a basic structural body of titania showing a titanium atom and oxygen atoms coordinated around the titanium atom which compose the titania, FIG. 3B is a top view of the basic structural body, FIG. 3C is an a-c cross sectional view of the basic structural body where a position of the titanium atom is set at the origin, and FIG. 3D is a b-c cross sectional view of the basic structural body where the titanium atom is set at the origin;

FIG. 4 is an exploded perspective view of a titania microcrystal which consists of combining the basic structural body shown in FIG. 3A;

FIG. 5A is an overall perspective view showing a titania microcrystal, FIG. 5B is a side view of the titania microcrystal in a b-c plane of FIG. 5A, and FIG. 5C is a side view of the titania microcrystal in an a-c plane of FIG. 5A;

FIG. 6A is a side view showing a one-dimensional structure of a titania crystal where a titania microcrystal is combined so that a straight line direction of the one-dimensional structure is aligned with a crystal axis c of the titania microcrystal that is a repeating unit structure of the one-dimensional structure, and FIG. 6B to FIG. 6D are side views showing the one-dimensional structures of the titania crystal where the titania microcrystal is combined by varying a tilt angle of the crystal axis c of the titania microcrystal against the straight line direction of the titania crystal; and

FIG. 7A is a vertical cross sectional view of a dye-sensitized solar cell according to an embodiment of the present invention, and FIG. 7B is experimental results showing electric power generation characteristics of the dye-sensitized solar cell.

### DESCRIPTION OF REFERENCE CHARACTERS

10 Basic structural body
20 Titania microcrystal
21 Unit cell
30 (30a, 30b, 30c, 30d) Titania crystal
40 Layered titania substrate
42 Base layer
43 Porous layer
50 Dye-sensitized solar cell
52 Counter electrode
B Irradiation light
L Electrolyte
E_{ff} Photoelectric conversion efficiency
J_{sc} Short circuit current density
R External load

### BEST MODE FOR EMBODYING THE INVENTION

Hereinafter, a specific element of an embodiment of a method for producing a titania crystal according to the present invention will be described.

A block copolymer (A) is a polymer surfactant having a hydrophobic block and a hydrophilic block, and for example, a polyoxyethylene block-polyoxypropylene block-polyoxyethylene block is preferably used.

The block copolymer is expressed with the following general formula.

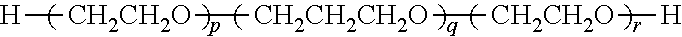

Here, it is preferable that p and r are not less than 20, q is not less than 10, and a total molecular weight is not less than 1000.

The block copolymer (A) is dissolved in water to prepare an aqueous solution whose hydrogen-ion exponent is set between pH1 and pH5.

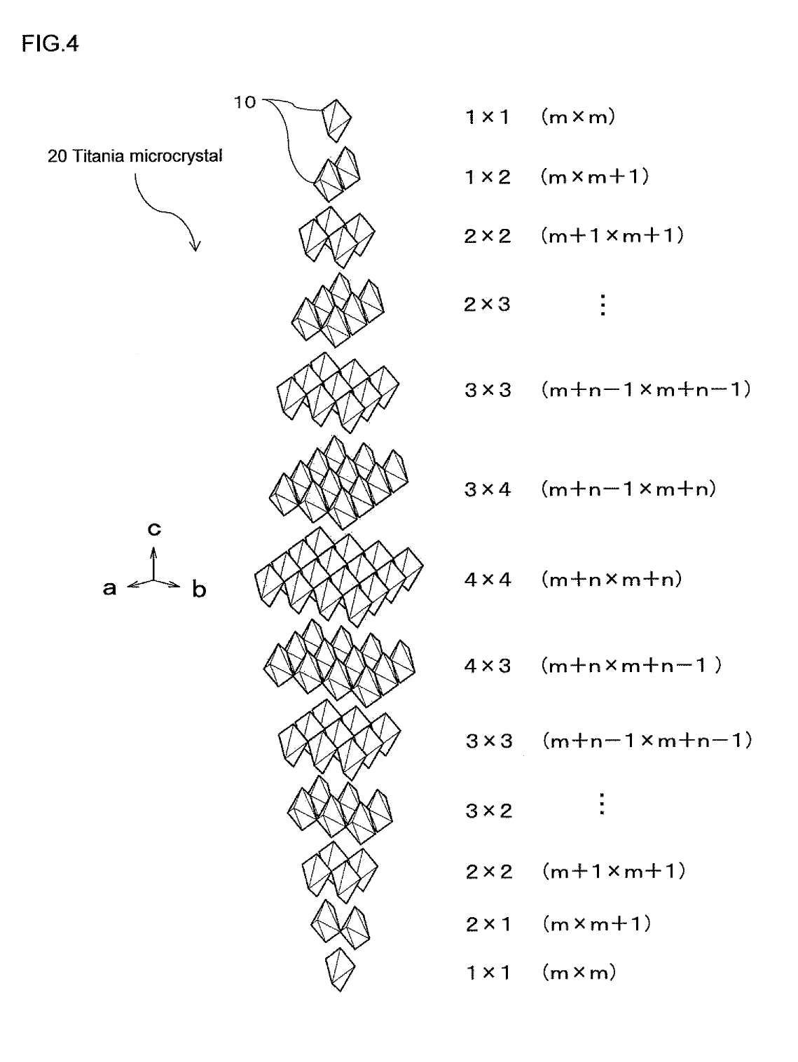

It is supposed that the block copolymer (A) has a function to control a reaction space for promoting a nucleation (see FIG. 3A) of a titania microcrystal as well as suppressing a growth of the titania microcrystal when titanium alkoxide (B), which is put into the aqueous solution later, is hydrolyzed to produce the titania microcrystal.

Therefore, when a temperature increases, a thermal molecular motion of the block copolymer (A) increases and a regular structure of the hydrophobic block and the hydrophilic block is broken, thereby resulting in decrease of the foregoing function. In contrast, when a temperature decreases, the thermal molecular motion decreases and the foregoing function becomes strong.

In addition, if a hydrogen-ion exponent of the aqueous solution of the block copolymer (A) is not less than pH1, a titania microcrystal to be produced by hydrolysis has a crystal structure of the anatase-type. On the other hand, if the hydrogen-ion exponent of the aqueous solution of the block copolymer (A) is less than pH1, a titania microcrystal to be produced by hydrolysis has a crystal structure of the rutile-type.

Furthermore, if the hydrogen-ion exponent of the aqueous solution of the block copolymer (A) is not more than pH5, a titania microcrystal to be produced by hydrolysis has a one-dimensional structure. On the other hand, if the hydrogen-ion exponent of the aqueous solution of the block copolymer (A) is more than pH5, a titania microcrystal to be produced by hydrolysis has a sheet-like shape or a tube-like shape which is formed by rolling the sheet-like shape, a rod-like shape, or a petal-like shape.

Namely, by setting the hydrogen-ion exponent of the aqueous solution of the block copolymer (A) between pH1 and pH5, a titania crystal having the anatase-type crystal structure and the one-dimensional structure can be obtained.

In addition, if a molecular weight of the block copolymer (A) is not less than 1000, the aqueous solution is given an appropriate viscosity, and as a result, an organic solvent (C) to be mixed later and titanium alkoxide (B) dissolved into the organic solvent (C) can be finely and homogeneously diffused into the aqueous solution, while preventing separation of the aqueous solution from the organic solvent (C).

Furthermore, if the molecular weight of the block copolymer (A) is not less than 1000, titania sol to be produced by a reaction of a mixed solution which is mixed as described above obtains a predetermined viscosity and contributes to improving coatability of the titania sol when the titania sol is coated on a surface of a substrate in a later process, and adhesiveness of a coating film after a heat treatment.

The titanium alkoxide (B) is an alcohol derivative where H in R—O—H of alcohol is substituted by titanium, and a compound which has at least one Ti—O—C bond.

The titanium alkoxide (B) is a starting material for producing titania gel, and includes for example, titanium tetra-methoxide, titanium tetra-ethoxide, titanium tetra-isopropoxide, titanium tetra-n-propoxide, titanium tetra-n-butoxide, titanium tetra-isobutoxide, titanium methoxypropoxide, and titanium dichloride diethoxide.

As the organic solvent (C), an organic solvent such as alcohol or multidentate ligand compound is used. The organic solvent (C) chemically modifies the titanium alkoxide (B) to thereby suppress that the titanium alkoxide (B) becomes non-anatase-type titania due to fast progress of hydrolysis, which will be described later.

As the alcohol, for example, isopropyl alcohol, methoxypropanol and butanol may be used. As the multidentate ligand compound, diketone compound, for example, biacetyl, benzyl and acetylacetone may be used. Especially, acetylacetone may be preferably used. These multidentate ligand compounds may be used independently, and also may be used by mixing with alcohol such as isopropyl alcohol, methoxypropanol and butanol.

A compounding ratio of the organic solvent (C) to the titanium alkoxide (B) is in a range of from 3:1 (solvent:titanium alkoxide) to 1:1 (solvent:titanium alkoxide) in mole ratio, or in the vicinity of the range. Using the compounding ratio described above, the titanium alkoxide is stabilized in the aqueous solution and an adjustment of the reaction rate of the hydrolysis in the reaction process becomes easy.

### (Explanation of Mixing Process and Reaction Process)

An aqueous solution where the block copolymer (A) is dissolved into water solvent is prepared. Next, an organic solution where the titanium alkoxide (B) is dissolved into the organic solvent (C) is prepared.

Then, the aqueous solution prepared as described abode is mixed with the organic solution and is sufficiently agitated to prepare a homogeneous mixed solution (mixing process).

Under this condition, the block copolymer (A) interfaces between the titanium alkoxide (B) and the water solvent to obtain a fine miscibility.

Next, the prepared mixed solution is encapsulated in a pressure resistant autoclave container, where a temperature thereof is set between 120° C. and 180° C. and is held for a predetermined time (several to dozens of hours) maintaining the temperature.

Therefore, an atmosphere inside the autoclave container is set to a saturated vapor pressure of the mixed solution at the setting temperature, and a hydrothermal reaction proceeds in the mixed solution to produce titania sol without vaporizing of the water solvent and the organic solvent (C) (reaction process).

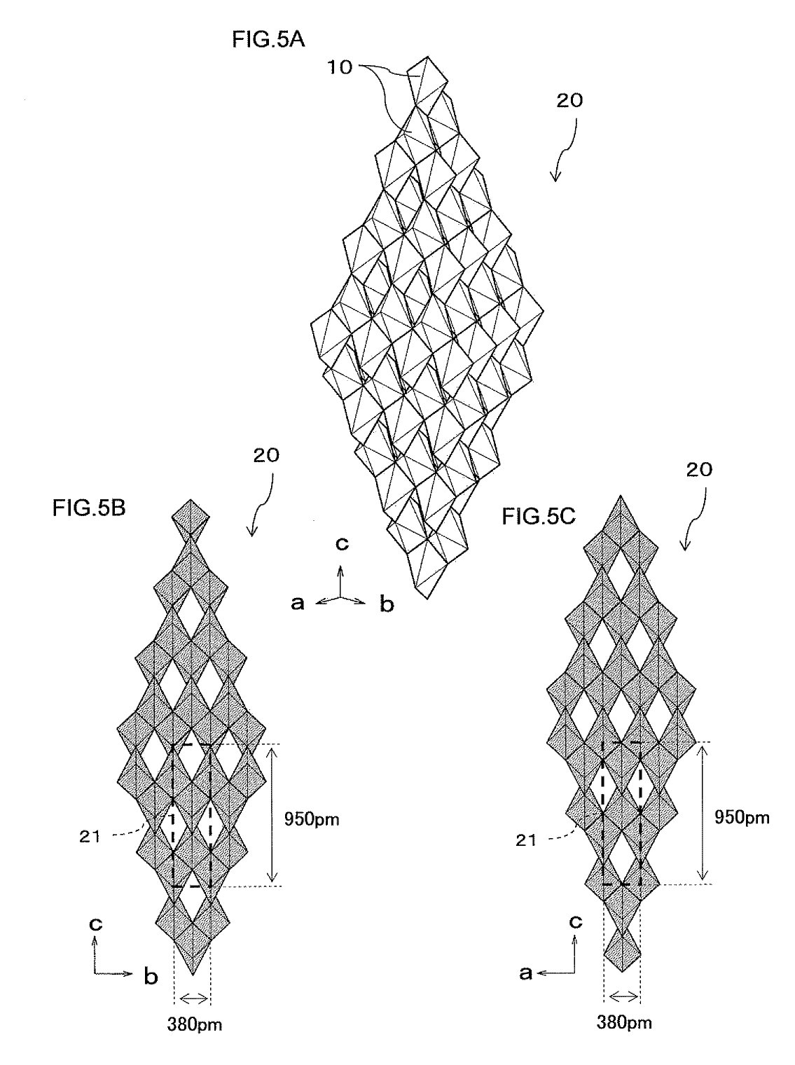

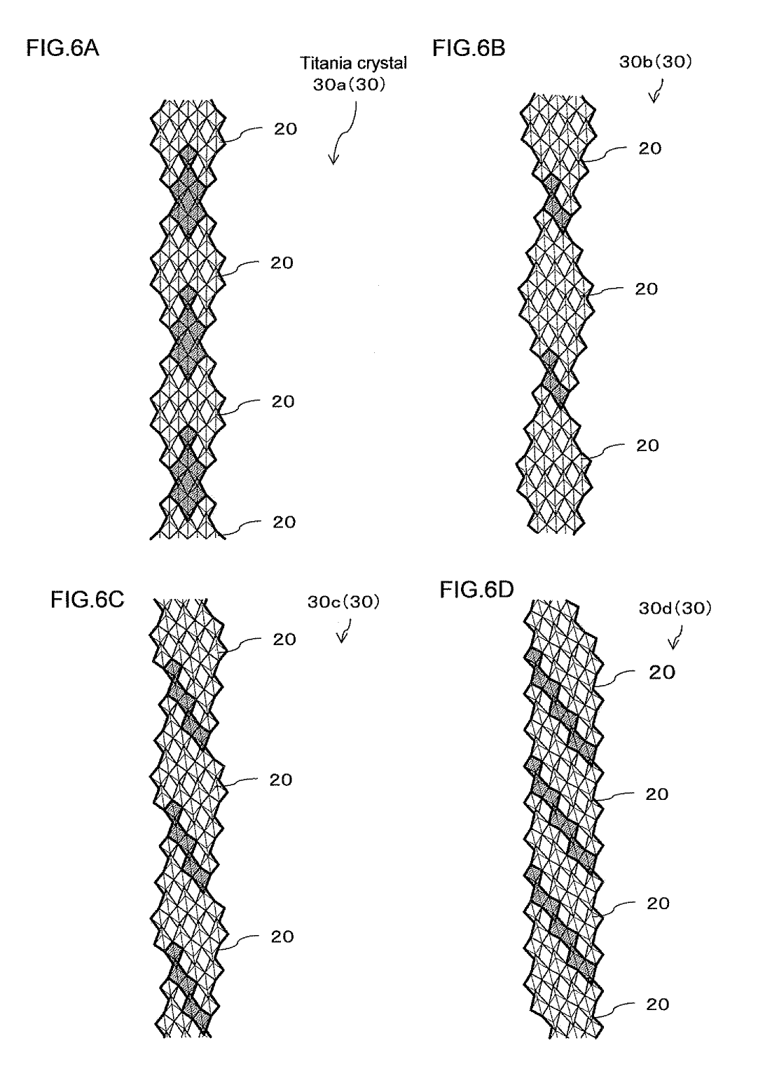

Namely, the titanium alkoxide (B) is hydrolyzed and a condensation polymerization reaction is repeated to produce a titania nucleation (see FIG. 3A as appropriate). The titania nucleation further grows to become a titania microcrystal 20 (see FIG. 4, FIG. 5A to FIG. 5C as appropriate).

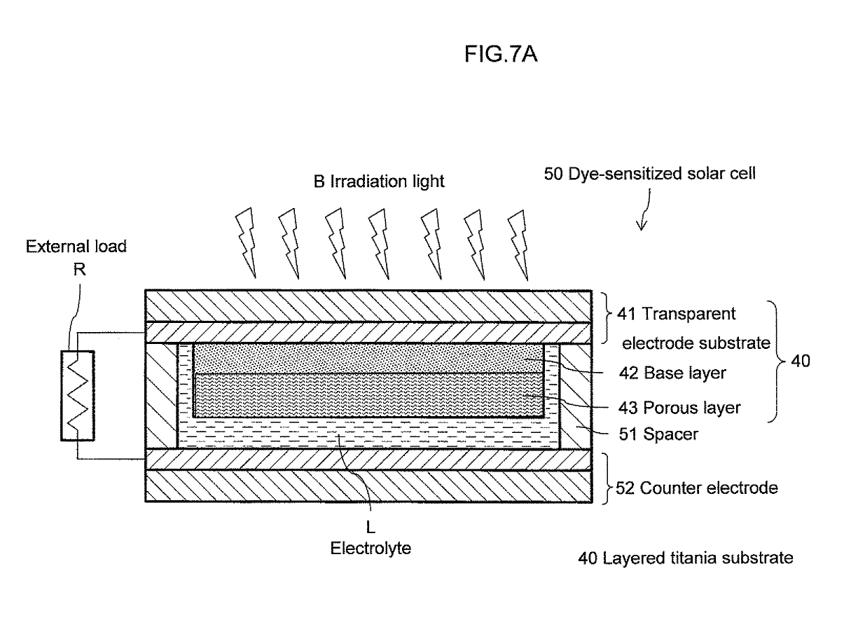

In addition, neighboring titania microcrystals 20 combine each other with a common crystal surface. The combination is repeated in a one direction to form a titania crystal 30 which has a one-dimensional structure (see FIG. 6A to FIG. 6D as appropriate). It is noted that the organic solvent (C) contributes to stabilizing the hydrolysis in the reaction process by chemically modifying the titanium alkoxide (B).

Here, if the setting temperature in the reaction process exceeds 180° C., the block copolymer (A) loses a function as a surfactant as described above. Therefore, the produced titania microcrystal combines one-dimensionally after growing further and a thick one-dimensional structure of the titania crystal is produced, accordingly.

On the other hand, if the setting temperature is less than 120° C., the function of the block copolymer (A) as a surfactant becomes too strong, and a growth of a titania nucleation is inhibited without combining with each other and a spherical titania particle having an aspect ratio of about 1 is produced, accordingly.

Namely, if the setting temperature of the mixed solution is between 120° C. and 180° C., a titania crystal having a fine diameter and a one-dimensional structure which has approximately a rectangular cross section whose one side length is in a range of about 4 nm to 20 nm, which corresponds to 10 to 50 cycles of titanium atomic arrangement, can be obtained.

### (Explanation of Baking Process)

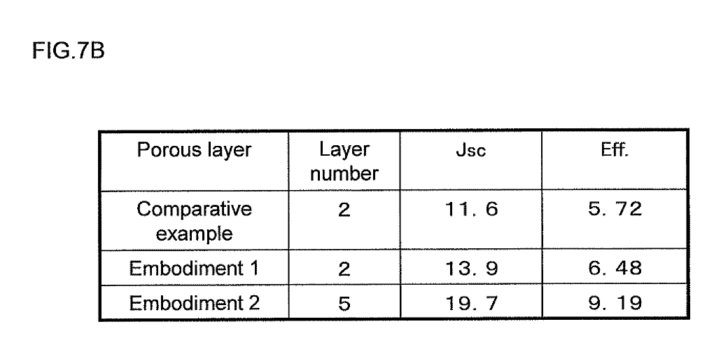

After the titania sol produced as described above is coated on a substrate, the titania sol is baked together with the substrate, and as a result, a layered titania substrate 40 (see FIG. 7A) that is formed by stacking a porous layer 43 including a titania crystal on a surface of the substrate can be manufactured.

Meanwhile, a baking condition of the titania sol is such that the titania sol is generally baked for 30 minutes to 2 hours at a setting temperature of 400° C. to 500° C.

It is preferable that the titania sol contains 7% to 12% of titania by weight for forming a high quality porous layer (film) on a substrate. For controlling the content of the titania, a solvent is vaporized at a reduced pressure when the titania is condensed, and the solvent is added when the titania is diluted.

If the titania content is less than 7% by weight, a titania crystal composing the porous layer 43 becomes too dense and desired photocatalytic characteristics and photoelectric conversion characteristics can not be obtained.

On the other hand, if the titania content is more than 12% by weight, a coatability of the titania sol decreases and it is likely to cause a non-uniformity of a film thickness and a peeling off of the film.

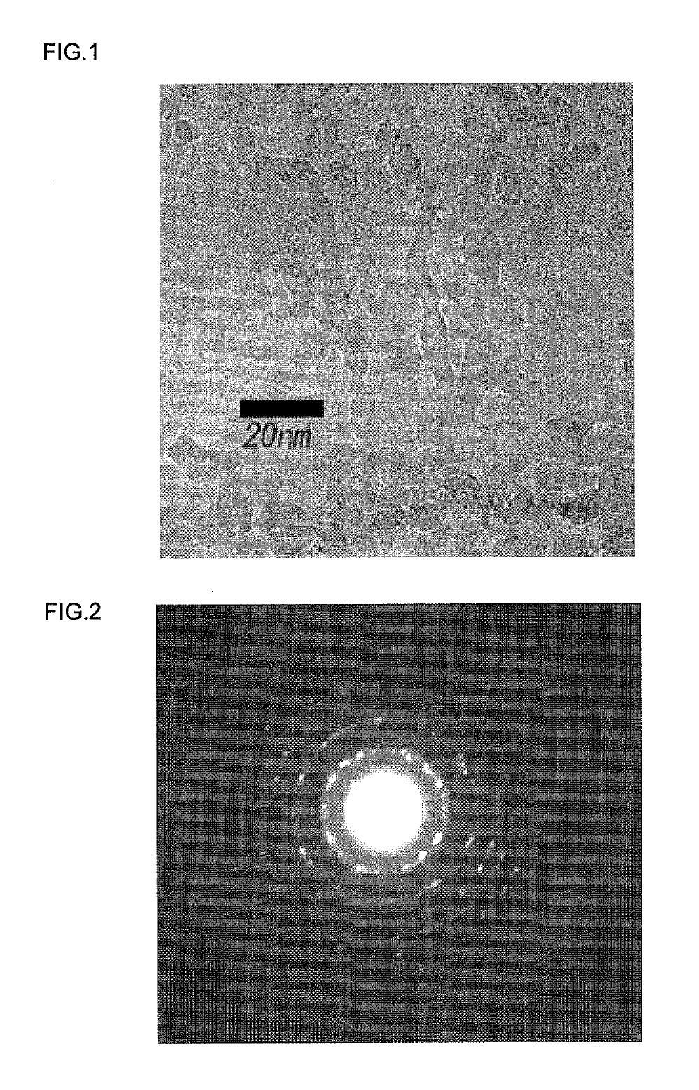

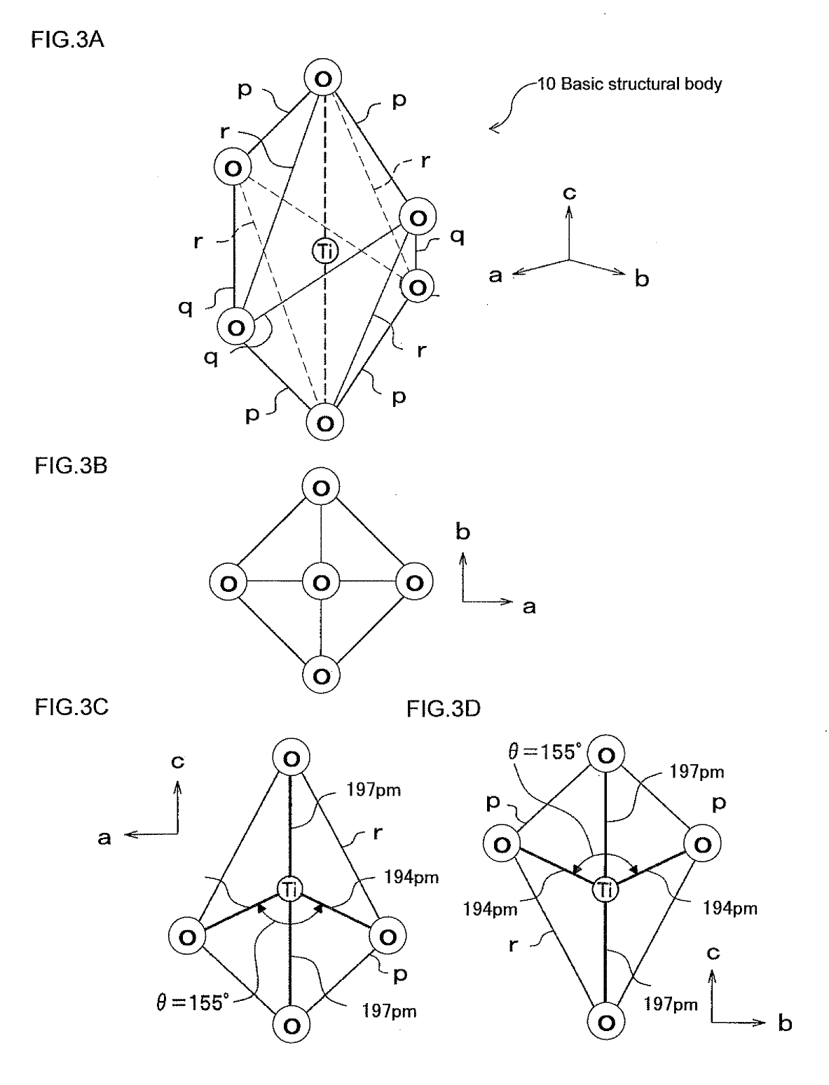

FIG. 1 is a TEM observation image of an aggregate of a titania crystal obtained as described above. FIG. 2 is an electron diffraction pattern of the aggregate of the titania crystal, where the pattern indicates that a crystal structure of the titania crystal is anatase-type.

As shown in the TEM image and the electron diffraction pattern, a titania crystal (see FIG. 6A to FIG. 6D as appropriate) produced by the method for producing a titania crystal according to the embodiment of the present invention has a crystal structure of the anatase-type whose crystal axis is aligned and a one-dimensional structure.

Next, an atomic arrangement of titania will be explained by referring to FIG. 3A to FIG. 3D.

FIG. 3A is a perspective view of a model (basic structural body) of a basic structure of titania, FIG. 3B is a top view of the basic structural body, FIG. 3C is an a-c cross sectional view of the basic structural body where the titanium atom is set at the origin, and FIG. 3D is a b-c cross sectional view of the basic structural body where the titanium atom is set at the origin.

Here, a, b, and c indicating coordinate axes respectively correspond to directions of a crystal axis a, a crystal axis b and a crystal axis c of a unit cell 21 (see FIG. 5B, FIG. 5C) of the anatase-type titania which belongs to a tetragonal system.

An anatase-type titania microcrystal 20 (see FIG. 5A to FIG. 5C) consists of combining a plurality of the basic structural bodies 10 having octahedral atomic arrangement where six oxygen atoms are coordinated around a titanium atom as shown by the perspective view in FIG. 3A (see FIG. 4 as appropriate).

The unit cell 21 (see FIG. 5B and FIG. 5C) of the anatase-type titania microcrystal 20 (see FIG. 5A to FIG. 5C) shows the tetragonal system where lattice constants are a=b=0.380 nm and c=0.950 nm, and contains four basic structural bodies 10 shown in FIG. 3A.

As shown in FIG. 3C and FIG. 3D, the basic structural body 10 has a Ti—O bonding length 197 pm long along the crystal axis c of the titania, a Ti—O bonding length 194 pm long along the crystal axes a, b, and an O—Ti—O bonding angle of 155°.

Twelve ridge lines forming eight surfaces of the basic structural body 10 can be sorted into three lengths p, q, and r (p<q<r).

The anatase-type titania microcrystal 20 will be explained by referring to FIG. 4 and FIG. 5A to FIG. 5C.

FIG. 4 is an exploded perspective view where a structure of a titania microcrystal 20 is separated into each layer.

As described above, the anatase-type titania microcrystal 20 is configured by sterically disposing the basic structural body 10 so that four shortest ridge lines p (see FIG. 3A) are shared with each other.

In addition, as shown in FIG. 4, the anatase-type titania microcrystal 20 is configured such that layers, where neighboring basic structural bodies 10 are in contact with each other to form a tetragonal arrangement at a vertex portion where two ridge lines q (p<q<r, see FIG. 3A) of the basic structural body 10 cross each other, are stacked by rotating 90° with each other.

In FIG. 4, each layer composing the titania microcrystal 20 consists of 1×1, 1×2, 2×2, 2×3, 3×3, 3×4, 4×4, 4×3, 3×3, 3×2, 2×2, 2×1, and 1×1 of the basic structural body 10 and is stacked with 13 steps in total. By generalizing the above structure, the titania microcrystal 20 can be defined such that the titania microcrystal 20 is configured by stacking each of layers where the basic structural body 10 is arranged by m×m, m×(m+1), . . . , (m+n−1)×(m+n), (m+n)×(m+n), (m+n)×(m+n−1), . . . , m×(m+1) and m×m (n, m: natural number).

In other words, a structure of the titania microcrystal 20 can be expressed such that the structure is an octahedral single crystal structure which is formed by stacking the basic structural body 10 and growing in the c-axis direction so that the basic structural body 10 shares the shortest ridge line p.

FIG. 5A is an overall perspective view of a titania microcrystal 20 that is formed by stacking and arranging the basic structural body 10, FIG. 5B is a side view of the titania microcrystal 20 in a b-c plane in FIG. 5A, and FIG. 5C is a side view of the titania microcrystal 20 in an a-c plane in FIG. 5A.

As described above, the anatase-type titania microcrystal 20 is characterized in that the anatase-type titania microcrystal 20 has a tetrahedral shape and a porous structure provided with through-holes as viewed from a side, and it is supposed that unique photocatalytic characteristics and photoelectric conversion characteristics thereof are based on the unique structure.

In addition, dotted lines in FIG. 5B and FIG. 5C indicate a unit cell 21 which is a unit indicating a structural cycle of the anatase-type titania.

Next, a morphology of the titania crystal 30 that is formed by combining the titania microcrystal 20 will be explained by referring to FIG. 6A to FIG. 6D.

A side view shown in FIG. 6A indicates a titania crystal 30a which is formed by combining a plurality of titania microcrystals 20, 20, . . . , along the crystal axis c. In FIG. 6A, several steps from the tip of the titania microcrystal 20 are shared with the neighboring titania microcrystals 20 to be unified.

Side views shown in FIG. 6B and FIG. 6C indicate titania crystals 30b, 30c which are formed by combining a plurality of titania microcrystals 20, 20, . . . , along a direction having a tilt angle against the crystal axis c. In FIG. 6B and FIG. 6C, the combination is performed so that a part of an oblique plane of the octahedral of the titania microcrystal 20 is shared with the neighboring titania microcrystal 20.

In FIG. 6A, FIG. 6B and FIG. 6C described above, a one-dimensional structure whose cross sectional area along the longitudinal direction of the titania crystal 30 varies periodically is obtained.

On the other hand, in FIG. 6D, since neighboring titania microcrystals 20 are combined so that an entire oblique plane of the octahedral is shared with each other, a one-dimensional structure whose cross sectional area is constant along the longitudinal direction of the titania crystal 30d is obtained.

It is noted that configurations of the titania crystal 30 shown in FIG. 6A to FIG. 6D are examples, and a number of titania microcrystal 20 to be combined is arbitrary. In addition, a position and a size of the part to be shared by neighboring titania microcrystals are also arbitrary. Furthermore, the one-dimensional structure of one titania crystal 30 includes not only a single configuration represented by those shown in FIG. 6A to FIG. 6D but also a combination thereof.

The illustrated these titania crystals 30 exemplify a titania crystal whose one side of a rectangular cross section has four cycles of titanium atomic arrangement for explanation. However, titania crystals having 10 to 50 cycles of the titanium atomic arrangement are preferable because they can be obtained by the foregoing method with high yield and have an excellent photocatalytic characteristics and photoelectric conversion characteristics (to be described later).

If the number of cycles is over 50 cycles, a surface area per unit volume of aggregates of the titania crystal 30 becomes small. Therefore, desired photocatalytic characteristics and photoelectric conversion characteristics can not be obtained.

A layered titania substrate where aggregates of the titania crystal 30 obtained as described above are stacked on a surface thereof can be utilized as a photocatalytic material. Specifically, the layered titania substrate can be used for efficiently conducting decomposition and removal of hazardous gas such as formaldehyde, elimination of air pollution, sterilization and eradication, and production of hydrogen through decomposition of water.

Next, in reference to FIG. 7A and FIG. 7B, an embodiment of a dye-sensitized solar cell 50 which utilizes aggregates of the titania crystal 30 according to the present invention will be described, and excellent photoelectric conversion characteristics thereof will be also described.

As illustrated, the dye-sensitized solar cell 50 includes a layered titania substrate 40, a counter electrode 52 which is disposed facing the layered titania substrate 40 and electrically connected to the layered titania substrate 40 via an external load R and an electrolyte L which is filled in a sealed space sealed by a spacer 51 and transports electrons in a direction from the counter electrode 52 to the layered titania substrate 40.

The layered titania substrate 40 consists of a transparent electrode substrate 41, a base layer 42 and a porous layer 43, and has functions to transmit an irradiation light B and collect electrons.

By configuring the dye-sensitized solar cell 50 as described above, the dye-sensitized solar cell 50 converts light energy of the irradiation light B into electric energy and supplies electric power to the external load R.

The transparent electrode substrate 41 is formed by coating one side of a plate-like transparent substrate 0.1 mm to 4 mm thick made of glass or plastic with a conductive transparent film 0.1 μm to 10 μm thick (for example, ITO film: Indium-Tin-Oxide), by using a well known method.

The transparent electrode substrate 41 has a function to transmit the irradiation light B without attenuating the light energy and a function to collect electrons emitted from the base layer 42 and the porous layer 43 into the ITO film and transporting the electrons to the external load R via wire connection.

The base layer 42 is disposed on a surface of the transparent electrode substrate 41 and contains spherical titania particles.

In consideration of poor physical adhesion between the porous layer 43 and the substrate surface, the base layer 42 is disposed for the purpose of increasing the adhesion by interfacing them and improving electrical and mechanical properties.

It is supposed that the poor physical adhesion between the substrate surface and the porous layer 43 formed of aggregates of the titania crystal 30 is attributed to originate from a small physical contact area between the aggregates of the titania crystal 30 and the substrate surface, which has a smooth surface, due to a bulky nature of the aggregates of the titania crystal 30 having a one-dimensional structure.

Therefore, it is preferable that the spherical titania particles composing the base layer 42 can secure a sufficient contacting area with the substrate surface and form voids through which iodine ions and I₃⁻ ions, which will be described later, can pass. Specifically, it is preferable that the titania particle has a grain size of 1 to 5 nm. The dye is also adsorbed on a surface of the spherical titania particle composing the base layer 42.

The porous layer 43 is the aggregates of the titania crystal 30 (see FIG. 6A to FIG. 6D) formed by the following process. The titania sol obtained in the foregoing reaction process is coated on one side of the base layer 42 and is subjected to the foregoing baking process to be stacked. Or, for providing a unity with the base layer 42, there may be a case that the spherical titania particles composing the base layer 42 is mixed with the one-dimensional titania crystal 30 (see FIG. 6A to FIG. 6D) for forming the porous layer 43.

As described above, the titania crystal 30 (see FIG. 6A to FIG. 6D) contained in the porous layer 43 is extremely fine, and a length of one side of the rectangular cross section of the titania crystal 30 is in a range of from 4 to 20 nm which corresponds to 10 to 50 cycles of the titanium atomic arrangement.

In addition, a crystal axis of the titania crystal 30 is aligned along the one-dimensional direction, and, since an amount of grain boundary at which a crystal alignment becomes discontinuous is reduced, the electrons flow smoothly, thereby resulting in improvement of photoelectric conversion characteristics of the dye-sensitized solar cell 50.

Furthermore, in a dense structure of the titania crystal 30 having the one-dimensional structure and fine diameter, since a sufficient surface area for adsorbing the dye can be secured and since the dense structure has the bulky nature, a continuous space of void which has a sufficient size through which iodine ions and I₃⁻ ions, which will be described alter, can pass with a small resistance is formed.

Therefore, even if a thickness of the porous layer 43 is increased, these iodine ions and I₃⁻ ions can pass through without being blocked.

Therefore, the porous layer 43 to be formed containing the one-dimensional titania crystal 30 can be made thicker than the one formed containing only the spherical titania particles, thereby resulting in increase in dye adsorption amount per unit light receiving area of the irradiation light B.

Due to the one-dimensional structure of the titania crystal 30 composing the porous layer 43, a current density to the transparent electrode substrate 41 through electron injection from the dye can be increased.

As described above, the dye adsorbs on a surface of the porous layer 43, is excited by absorbing the irradiation light B, and injects electrons into the porous layer 43.

The electron injection by the dye occurs when the electrons are excited to an energy level 0.2 eV higher than a conduction band of the titania composing the porous layer 43 by absorbing light energy of the irradiation light B.

Here, as the dye, a metal complex or organic dye of, for example, ruthenium complex, especially, ruthenium bipyridine complex, phthalocyanine, cyanine, merocyanine, porphyrin, chlorophyll, pyrene, methylene blue, thionine, xanthene, coumalin and rhodamine, and a derivative thereof may be used.

In addition, adsorption of dye on a surface of the porous layer 43 may be performed by dipping the transparent electrode substrate 41 into a solution containing the dye dispersed therein for a predetermined time.

The counter electrode 52 is a platinum electrode facing the transparent electrode substrate 41 across the porous layer 43 and electrically connected to the transparent electrode substrate 41 via the external load R.

In addition, on peripheries of the counter electrode 52 and the transparent electrode substrate 41, a spacer 51 is disposed so as to set a distance between both the electrodes and seal a closed space.

The electrolyte L is filled in the closed space formed between the transparent electrode substrate 41 and the counter electrode 52 and transports electrons in a direction from the counter electrode 52 to the transparent electrode substrate 41.

The electrolyte L is not specifically limited as long as the electrolyte L contains ions capable of providing electrons to the dye which injected electrons to the porous layer 43. However, an iodine-based electrolyte containing I⁻/I₃⁻ is preferably used. Other than the iodine-based electrolyte, a solution which is prepared by dissolving an electrolyte, for example, Br⁻/Br₃⁻-based electrolyte or quinone/hydroquinone-based electrolyte in an electrochemically inactive solvent such as acetonitrile, propyrene carbonate and ethyrene carbonate (and mixed solvent of these) may be used.

Next, an operating principle of the dye-sensitized solar cell 50 will be explained. First, when the irradiation light B enters the transparent electrode substrate 41 of the dye-sensitized solar cell 50, most of the irradiation light B reaches the porous layer 43 by passing through the transparent electrode substrate 41 without absorption. If the irradiation light B irradiates the dye adsorbed on surfaces of the base layer 42 and the porous layer 43, the dye is excited by absorbing light energy of the irradiation light B. If the excitation reaches an energy level 0.2 eV higher than the conduction band of titania, electrons are injected into the titania from the dye.

Meanwhile, even if the dye is excited by absorbing the irradiation light B, when the dye is left as it is, the injected electrons recombine with the dye. Therefore, before the recombination of the electrons takes place, ions surrounding the electrons in the electrolyte L provide electrons to the dye by migrating in the electrolyte L. Since the voids of the porous layer 43 through which the ions migrate as described above have a small migration resistance of the ions and the dye adsorbs at high density, electrons can be provided to the dye from the ions before the electrons injected into the titania recombine.

Then, the ions oxidized by providing electrons to the dye can migrate toward the counter electrode 52, which is the opposite migrating direction of before, through the voids of the porous layer 43 without receiving a large migration resistance. When the oxidized ions reach the counter electrode 52, the oxidized ions are reduced by accepting electrons from the counter electrode 52.

As described above, ions in the electrolyte L migrate back and forth between the dye and the counter electrode 52 and repeat oxidation-reduction reaction. Accordingly, a potential gradient is generated between the transparent electrode substrate 41 and the counter electrode 52.

Then, if the transparent electrode substrate 41 and the counter electrode 52 are shunted via the external load R, an electric power is supplied to the external load R. In this case, although the ions in the electrolyte L continuously migrate back and forth in the voids of the porous layer 43, the migration resistance is small. Accordingly, a high power and a high efficiency can be achieved by the dye-sensitized solar cell 50.

### Embodiment

Hereinafter, an embodiment demonstrating advantages of a dye-sensitized solar cell which utilizes a titania crystal having a one-dimensional structure according to the present invention will be explained.

### (Formulation of Base Layer 42)

First, a titania gel (hereinafter, referred to as “base gel”) containing a titania particle having a particle size of 1 to 5 nm at 0.8M is prepared.

A Sellotape (registered trademark) with a predetermined hole is put on an ITO transparent conductive film (Indium-Tin-Oxide) (manufactured by GEOMATEC Corporation) having a sheet resistance of 2Ω/□, and the base gel is placed on the hole, spread by a glass rod and baked for ten minutes at 450° C. after drying, then, a thin film is obtained. The foregoing processes are repeated twice, and the base layer 42 (see FIG. 7A) is obtained.

### (Formulation of Porous Layer 43)

Next, a titania gel (hereinafter, referred to as “invention gel”) containing the titania crystal 30 of the one-dimensional structure is mixed with the base gel, and a titania gel (hereinafter, referred to as “embodiment gel”) having 12% of titania concentration by weight is prepared.

The embodiment gel is placed on the base layer 42, spread by a glass rod and baked for 10 minutes at 450° C. after drying, then, a thin film is obtained. A layered titania substrate 40 having the porous layer 43 consisting of two layers which are formed by repeating the foregoing processes two times is named “Embodiment 1”, and a layered titania substrate 40 having the porous layer 43 consisting of five layers formed by repeating the foregoing processes five times is named “Embodiment 2”.

After the baking of the porous layer 43 is completed, the layered titania substrate 40 is dipped into an ethanol solution of ruthenium dye N719 at concentration of 3×10⁻⁴ M for 20 hrs to adsorb the dye on inner surfaces thereof.

The counter electrode 52 which is formed by evaporating platinum on an ITO transparent conductive film is overlapped with the layered titania substrate 40 to face with each other, and the electrolyte L is filled between the electrodes to configure the dye-sensitized solar cell 50 (see FIG. 7A). Meanwhile, a cell size was 5 mm×5 mm and the electrolyte L was prepared by dissolving 0.6M DMPII (1,2-Dimethyl-3-propylimidazoliumiodide), 0.1M LiI, 0.05M I₂ and 0.5M TBP (tert-butylpyridine) in acetonitrile.

### COMPARATIVE EXAMPLE

In the foregoing procedure, instead of the embodiment gel, the following titania gel (hereinafter, referred to as “comparative example gel”) was used, which was prepared as follows. A commercially available titania particle P25 (manufactured by NIPPON AEROSIL CO., LTD.) was added in amount of 8% by weight to the base gel which contained titania particles each having a particle size of 1 to 5 nm at concentration of 0.4M to prepare the comparative example gel which had a titania concentration of 10.5% by weight.

A layered titania substrate which has a porous layer consisting of two layers of the comparative example gel is named “Comparative example”. A procedure for fabricating a dye-sensitized solar cell using the layered titania substrate of the comparative example is the same with the embodiment.

### (Measurement Results)

A performance of a dye-sensitized solar cell was measured by irradiating an irradiation light on a side of the transparent electrode. A pseudo-solar light (100 mW/cm²) radiated from a solar simulator manufactured by Yamashita Denso Corporation was used and a current-voltage curve was measured using an I-V measurement system manufactured by Peccell Technologies, Inc.

The measurement results are shown in FIG. 7B.

In the comparison result between the Comparative example (titania of P25) and the Embodiment 1 (titania of one-dimensional structure), where a thickness (layer number) of the porous layer 43 was the same, values of short circuit current J_{sc} and photoelectric conversion efficiency E_{ff} of the Embodiment 1 are superior to those of the Comparative example. Accordingly, it was suggested by the result that the layered titania substrate 40 utilizing a titania microcrystal of one-dimensional structure has excellent photcatalytic characteristics and photoelectric conversion characteristics.

Next, in the comparison result between the Embodiment 1 (2 layers) and the Embodiment 2 (5 layers), where the thickness (layer number) of the porous layer 43 was varied, values of the short circuit current J_{sc} and the photoelectric conversion efficiency E_{ff} of the Embodiment 2 are superior to those of the Embodiment 1. On the other hand, although not shown, with respect to the comparison result between the Comparative example (2 layers) and a corresponding Comparative example (5 layers), improvement of the short circuit current J_{sc} and the photoelectric conversion efficiency E_{ff} by increasing the layer number was not found.

According to the foregoing results, it can be said that since a migration resistance of ions of the electrolyte L in the porous layer 43 using titania of one-dimensional structure is small, a thickness of the porous layer 43 may be increased for improving a dye density of the irradiation surface, thereby resulting in improvement of power generation characteristics of the dye-sensitized solar cell 50.

What is claimed is:

1. A method for producing a titania crystal, comprising steps of:
a mixing process for mixing at least an aqueous solution which contains a block copolymer (A) having a hydrophobic block and a hydrophilic block and is set between pH1 and pH5 with an organic solvent (C) containing titanium alkoxide (B) dissolved therein to prepare a mixed solution;
a reaction process for setting a temperature of the mixed solution between 120° C. and 180° C., controlling a pressure of atmosphere at a saturated vapor pressure of the mixed solution at the setting temperature, and reacting the mixed solution to produce titania sol; and
a baking process for heating the titania sol to produce a titania microcrystal and baking a titania crystal which is formed by combining the titania microcrystal one-dimensionally.

2. The method for producing a titania crystal according to claim 1, further comprising a step of:
adopting a polyoxyethylene block-polyoxypropylene block-polyoxyethylene block, which has a molecular weight not less than 1000, as the block copolymer (A).

3. The method for producing a titania crystal according to claim 1, further comprising a step of:
controlling a content of titania in the titania sol to be produced in the reaction process between 7% and 12% by weight.

4. A titania crystal to be produced by the method for producing a titania crystal according to claim 1.

5. A layered titania substrate which is formed by stacking a porous layer containing the titania crystal according to claim 1, the titania crystal being produced by coating the titania sol obtained by the reaction process in the method for producing a titania crystal according to claim 1 and being subjected to the baking process.

6. The layered titania substrate according to claim 5,
wherein the porous layer is formed on a base layer containing spherical titania particles disposed on a surface of a substrate.

7. A dye-sensitized solar cell, comprising:
the layered titania substrate according to claim 5 which has a function to transmit an irradiation light and a function to collect electrons;
dye which is adsorbed on a surface of the porous layer and injects electrons into the porous layer when the dye is excited by absorbing the irradiation light;
a counter electrode which faces the layered titania substrate across the porous layer and is electrically connected to the layered titania substrate via an external load; and
an electrolyte which is encapsulated between the layered titania substrate and the counter electrode and transports electrons in a direction from the counter electrode to the layered titania substrate.

8. A titania crystal which has a one-dimensional structure where a plurality of anatase-type titania microcrystals are combined by aligning crystal axes thereof and a one side of a substantially rectangular cross section of the one-dimensional structure has a length corresponding to 10 to 50 cycles of atomic arrangement of titanium.

9. A layered titania substrate which is formed by stacking a porous layer containing the titania crystal according to claim 8.

10. The layered titania substrate according to claim 9,
wherein the porous layer is formed on a base layer containing spherical titania particles disposed on a surface of a substrate.

11. A dye-sensitized solar cell, comprising:
the layered titania substrate according to claim 9 which has a function to transmit an irradiation light and a function to collect electrons;
dye which is adsorbed on a surface of the porous layer and injects electrons into the porous layer when the dye is excited by absorbing the irradiation light;
a counter electrode which faces the layered titania substrate across the porous layer and is electrically connected to the layered titania substrate via an external load; and
an electrolyte which is encapsulated between the layered titania substrate and the counter electrode and transports electrons in a direction from the counter electrode to the layered titania substrate.
